(19) United States
(12) Patent Application Publication
(10) Pub. No.: US 2024/0274500 A1
(43) Pub. Date: Aug. 15, 2024

(54) SEMICONDUCTOR DEVICE AND METHOD FOR MANUFACTURING THE SAME

(71) Applicant: Mitsubishi Electric Corporation, Tokyo (JP)

(72) Inventors: Yoshihiro YAMAGUCHI, Tokyo (JP); Takeshi HIGASHIHATA, Tokyo (JP)

(73) Assignee: Mitsubishi Electric Corporation, Tokyo (JP)

(21) Appl. No.: 18/690,472

(22) PCT Filed: Dec. 28, 2021
(86) PCT No.: PCT/JP2021/048880

§ 371 Date: Mar. 8, 2024

(51) Int. Cl. H01L 23/373; H01L 21/02

(52) U.S. Cl. CPC H01L 23/3735; H01L 21/02288; H01L 21/02378

(57) ABSTRACT

Porous SIC (2) is impregnated with metal (9) including Al as a mam component. A circuit pattern (4) is provided on a ceramic substrate (3). A semiconductor clip (5) is joined to the circuit pattern (4). The porous SiC (2) includes a holding portion (7) that holds the ceramic substrate (3).

### FIELD

The present disclosure relates to a semiconductor device and a method for manufacturing the same.

### BACKGROUND

As the operating temperature of semiconductor chips increases, the temperature of the entire module increases, and there is a concern about its effect on the life against temperature change. Particularly, a solder joint portion is susceptible to the effect, which imposes great restrictions on the life of the module. In recent years, development of Ag-based and Cu-based joint materials that have higher heat cycle resistance than solder has proceeded. However, while its application to small-area joining such as joining of a chip has advanced, it is difficult to secure joint reliability for large-area joining such as joining of an insulating substrate. Further, the Ag-based and Cu-based joint materials are more expensive than solder and thus not appropriate to be used for a large area. Against this, a base plate obtained by impregnating porous SiC with Al by applying a pressure and integrally molded with an insulating substrate has been proposed (see, for example. PTL. 1), but it has not been put to practical use.

### CITATION LIST

### Patent Literature

[PTL 1] JP 2003-297988 A

### SUMMARY OF THE INVENTION

### Problems to be Solved by the Invention

In PTL 1, the upper surfaces of a ceramic substrate and porous SiC are located on the same level, and aluminum foil is provided so as to cover the upper surfaces to hold the ceramic substrate. However, since it is necessary to provide aluminum foil, the production cost increases. Further, it is necessary to locate the upper surfaces of the ceramic substrate and the porous SiC on the same level, and thus, the degree of freedom in design is small.

The present disclosure has been made to solve the problems as described above, and an object thereof is to provide a semiconductor device with a high degree of freedom in design and capable of reducing its production cost, and a method for manufacturing the same.

### Solution to Problem

A semiconductor device according to the present disclosure includes: porous SiC impregnated with metal including Al as a main component: a ceramic substrate; a circuit pattern provided on the ceramic substrate; and a semiconductor chip joined to the circuit pattern, wherein the porous SiC includes a bolding portion that holds the ceramic substrate.

### Advantageous Effects of Invention

In the present disclosure. the holding portion that holds the ceramic substrate is provided by changing the shape of the porous SiC. Thus, it is not necessary to provide aluminum foil for holding the ceramic substrate, which can reduce the production cost. Further, it is not necessary to locate the upper surfaces of the ceramic substrate and the porous SiC on the same level, which increases the degree of freedom in design.

### BRIEF DESCRIPTION OF THE DRAWINGS

FIG. 1 is a cross-sectional view illustrating a semiconductor device according to a first embodiment.

FIG. 2 is a top view illustrating the semiconductor device according to the first embodiment.

FIG. 3 is a view for explaining the method for manufacturing the same according to the first embodiment.

FIG. 4 is a top view illustrating a semiconductor device according to a second embodiment.

FIG. 5 is a cross-sectional view illustrating a semiconductor device according to a third embodiment.

FIG. 6 is a cross-sectional view illustrating a semiconductor device according to a fourth embodiment.

FIG. 7 is a top view illustrating a semiconductor device according to a fifth embodiment.

### DESCRIPTION OF EMBODIMENTS

A semiconductor device and a method for manufacturing the same according to the embodiments of the present disclosure will be described with reference to the drawings. The same components will be denoted by the same symbols. and the repeated description thereof may be omitted.

### First Embodiment

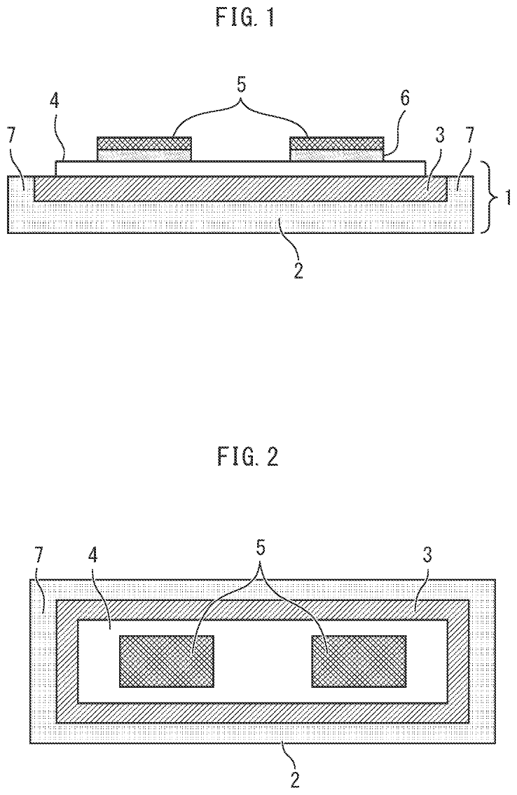

FIG. 1 is a cross-sectional view illustrating a semiconductor device according to a first embodiment. FIG. 2 is a top view illustrating the semiconductor device according to the first embodiment. This semiconductor device is a power module. An integrated base plate l includes porous SiC 2 impregnated with metal including Al as a main component, a ceramic substrate 3, and a circuit pattern 4 provided on the ceramic substrate 3. The porous SiC 2 includes a holding portion 7 that holds the ceramic substrate 3. The holding portion 7 holds the ceramic substrate 3 by surrounding the entire outer periphery of the ceramic substrate 3.

The thickness of the integrated base plate 1 is, for example, equal to or greater than 3 mm and equal to or less than 8 mm. The integrated base plate 1 has high heat dissipation, and the heat dissipation is caused mainly by the ceramic substrate 3. The ceramic substrate 3 is formed with, for example, alumina (Al₂O₃), aluminum nitride (AIN). silicon nitride (SiN), or the like.

A semiconductor chip 5 is joined to the circuit pattern 4 with joint material 6 such as solder material. Ag sintered material or Cu sintered material. Examples of the semiconductor chip 5 are an IGBT and a diode of Si, an MOSFET and an SBD of SiC, and the like. An upper electrode of the semiconductor chip 5 is electrically connected to a terminal (not illustrated) with a wire (not illustrated). Note that an exterior case may be attached to the integrated base plate 1. Further, the inside of the exterior case may be sealed with sealing resin.

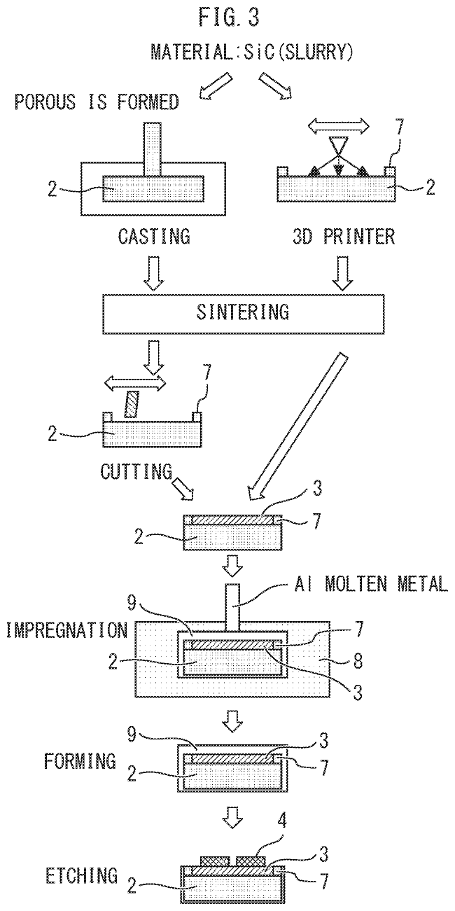

Subsequently. a method for manufacturing the same of the present embodiment will be described. FIG. 3 is a view for explaining the method for manufacturing the same according to the first embodiment. First, porous SiC 2 formed by casting and sintering SiC (slurry) is cut to form the holding portion 7. Alternatively, the porous SiC 2 including the holding portion 7 may be formed using a 3D printer. Then, the ceramic substrate 3 is held by the holding portion 7 of the formed porous SiC 2.

Then, the porous SiC 2 on which the ceramic substrate 3 is placed is positioned in a mold 8 for shaping the integrated base plate 1. The porous SiC 2 is impregnated with metal 9 including Al as a main component through. for example. pressureless impregnation, pressure impregnation. die cast. or the like. Then, the metal 9 left on the upper surface of the ceramic substrate 3 is etched to form the circuit pattern 4. Thereafter, the semiconductor chip 5 is joined to the circuit pattern 4 with the joint material 6, and wire bonding and the like are performed.

In the related art. the upper surfaces of the ceramic substrate and the porous SiC are located on the same level, and aluminum foil is provided so as to cover the upper surfaces to hold the ceramic substrate. In contrast. in the present embodiment. the holding portion 7 that holds the ceramic substrate 3 is provided by changing the shape of the porous SiC 2. Thus, it is not necessary to provide aluminum foil for holding the ceramic substrate 3, which can reduce the production cost. Further. it is not necessary to locate the upper surfaces of the ceramic substrate 3 and the porous SiC 2 on the same level, which increases the degree of freedom in design.

Further, the ceramic substrate 3 and the base plate can be integrated without solder joint. The integrated base plate 1 has high heat dissipation, so that it is possible to achieve heat cycle resistance and high heat dissipation.

Further, pressureless impregnation is preferably used in impregnating the porous SiC 2 with metal. Pressureless impregnation can simplify a process compared to pressure impregnation. Further, after impregnating the porous SiC 2 with the metal 9. the metal 9 on the ceramic substrate 3 is etched to form the circuit pattern 4. This can simplify the process and reduce the production cost.

### Second Embodiment

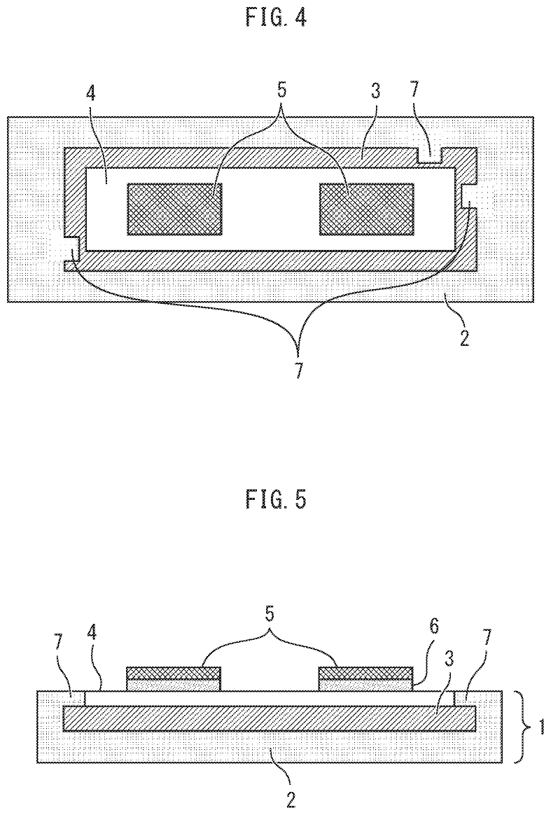

FIG. 4 is a top view illustrating a semiconductor device according to a second embodiment. A ceramic substrate 3 has a quadrangular shape in plan view. Porous SiC 2 includes holding portions 7 that are in contact with side surfaces of the ceramic substrate 3 at three or more locations and hold the ceramic substrate 3. The holding portions 7 respectively hold three different sides of the quadrangular ceramic substrate 3. The ceramic substrate 3 is inserted inside the holding portions 7 from a portion where the holding portion 7 is not provided.

The position of the ceramic substrate 3 is determined by the holding portions 7 at the three or more locations. Further, stress to the ceramic substrate 3 can be alleviated. Still further. compared to the first embodiment in which the porous SiC 2 is in contact with the entire side surface of the ceramic substrate, it is possible to reduce the raw materials, so that it is possible to largely reduce the production cost, particularly, in a case where the porous SiC 2 is formed using a 3D printer. Other configurations and effects are similar to those in the first embodiment.

### Third Embodiment

FIG. 5 is a cross-sectional view illustrating a semiconductor device according to a third embodiment. Porous SiC 2 includes key-shaped holding portions 7 that hold the ceramic substrate 3. Each key-shaped holding portion 7 is provided so as to embrace the side surfaces and the upper surface of the ceramic substrate 3. This can prevent the ceramic substrate 3 from being displaced during impregnation. It is therefore possible to secure a process margin for impregnation, so that it is possible to improve productivity. Other configurations and effects are similar to those in the second embodiment.

### Fourth Embodiment

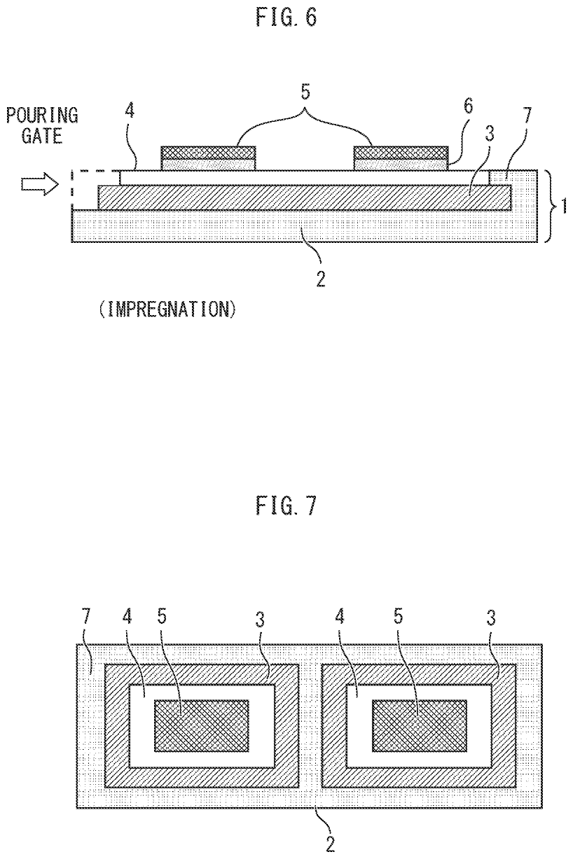

FIG. 6 is a cross-sectional view illustrating a semiconductor device according to a fourth embodiment. Holding portions 7 are provided so as to respectively hold three different sides of a ceramic substrate 3. One side of the ceramic substrate 3 on which no holding portion 7 is provided is set as the pouring gate side from which metal 9 is to be supplied during impregnation. This can secure flowability of the metal 9 from the pouring gate side and achieve both positioning and holding of the ceramic substrate 3. Other configurations and effects are similar to those in the third embodiment.

### Fifth Embodiment

FIG. 7 is a top view illustrating a semiconductor device according to a fifth embodiment. While only one large-sized ceramic substrate 3 is used in the first embodiment, in the present embodiment, two or more separate ceramic substrates are provided. Porous SiC 2 holds the two or more separate ceramic substrates 3. By using pieces of ceramic substrates which are more inexpensive than a large-sized ceramic substrate, it is possible to reduce the production cost. Further, it is possible to alleviate stress to the ceramic substrate 3. Other configurations and effects are similar to those in the first embodiment.

The semiconductor chip 5 is not limited to a chip formed of silicon, but instead may be formed of a wide-bandgap semiconductor having a bandgap wider than that of silicon. The wide-bandgap semiconductor is, for example, a silicon carbide, a gallium-nitride-based material. or diamond. A semiconductor chip formed of such a wide-bandgap semiconductor has a high voltage resistance and a high allowable current density. and thus can be miniaturized. The use of such a miniaturized semiconductor chip enables the miniaturization and high integration of the semiconductor device in which the semiconductor chip is incorporated. Further. since the semiconductor chip has a high heat resistance, a radiation fin of a heatsink can be miniaturized and a water-cooled part can be air-cooled. which leads to further miniaturization of the semiconductor device. Further, since the semiconductor chip has a low power loss and a high efficiency. a highly efficient semiconductor device can be achieved.

### REFERENCE SIGNS LIST

2 porous SiC; 3 ceramic substrate; 4 circuit pattern; 5 semiconductor chip; 7 holding portion; 9 metal

1. A semiconductor device comprising:
porous SiC impregnated with metal including Al as a main component;
a ceramic substrate;
a circuit pattern provided on the ceramic substrate; and
a semiconductor chip joined to the circuit pattern,
wherein the porous SiC includes a holding portion that holds the ceramic substrate.

2. The semiconductor device according to claim 1, wherein the holding portion holds the ceramic substrate by surrounding an entire outer periphery of the ceramic substrate.

3. The semiconductor device according to claim 1, wherein the holding portion is in contact with a side surface of the ceramic substrate at three or more locations and holds the ceramic substrate.

4. The semiconductor device according to claim 3, wherein the ceramic substrate has a quadrangular shape in plan view, and
the holding portion holds three different sides of the ceramic substrate.

5. The semiconductor device according to claim 1, wherein the holding portion is key-shaped.

6. The semiconductor device according to claim 1, wherein the ceramic substrate is divided into two or more pieces.

7. The semiconductor device according to claim 1, wherein the semiconductor chip is formed of a wide-bandgap semiconductor.

8. A method for manufacturing a semiconductor device comprising:
forming porous SiC including a holding portion;
holding a ceramic substrate by the holding portion;
impregnating the porous SiC with metal including Al as a main component;
after impregnating the porous SiC with the metal, etching the metal left on an upper surface of the ceramic substrate to form the circuit pattern; and
joining the semiconductor chip to the circuit pattern.

9. The method for manufacturing a semiconductor device according to claim 8, wherein pressureless impregnation is used in impregnating the porous SiC with the metal.

10. The method for manufacturing a semiconductor device according to claim 8, wherein one side of the ceramic substrate on which the holding portion is not provided is set as a pouring gate side from which the metal is to be supplied during impregnation.

11. The method for manufacturing a semiconductor device according to claim 8, wherein the porous SiC is cut to form the holding portion.

12. The method for manufacturing a semiconductor device according to claim 8, wherein the porous SiC including the holding portion is formed using a 3D printer.
